(19) United States
(12) Patent Application Publication
(10) Pub. No.: US 2014/0001923 A1
(43) Pub. Date: Jan. 2, 2014

(54) COMPOSITE POLARIZATION TYPE PIEZOELECTRIC ACTUATOR

(71) Applicant: CHUNG-YUAN CHRISTIAN UNIVERSITY, Tao Yuan County (TW)

(72) Inventors: Yung TING, Tao Yuan County (TW); SHEUAN-PERNG LIN, Tao Yuan County (TW); YUN-JUI SHIEH, Tao Yuan County (TW)

(73) Assignee: CHUNG-YUAN CHRISTIAN UNIVERSITY, Tao Yuan County (TW)

(21) Appl. No.: 13/859,331

(22) Filed: Apr. 9, 2013

(30) Foreign Application Priority Data
Jun. 27, 2012 (TW) 101123053

(51) Int. Cl. H02N 2/00; H02N 2/10; H01L 41/09

(52) U.S. Cl. CPC H02N 2/0045; H01L 41/0993; H02N 2/103
USPC 310/323.16; 310/357

(57) ABSTRACT

The present invention discloses a composite polarization type piezoelectric actuator comprising a ceramic element having a first polarizing region and a second polarizing region, wherein the first polarizing region has a first polarizing direction different from a second polarizing direction of the second polarizing region. When a voltage is applied to the composite polarization type piezoelectric actuator, an end face of the ceramic element is deformed. When a pulse wave voltage is applied to the composite polarization type piezoelectric actuator, the end face of the ceramic element generates an elliptical motion.

### BACKGROUND OF THE INVENTION

1. Field of the Invention

The present invention relates to a composite polarization type piezoelectric actuator, and more particularly, to a composite polarization type piezoelectric actuator having a plurality of polarizing regions.

2. Description of the Related Art

The piezoelectric effect is achieved by deforming a material to convert mechanical energy into electrical energy, and vice versa. Since the piezoelectric characteristics of BaTiO₃ were discovered in 1942, various piezoelectric materials have been developed. For example, lead zirconate titanate (PZT), discovered in 1950, is the most widely used piezoelectric ceramic material. Generally speaking, piezoelectric ceramic materials have features such as a small form factor, quick response time, and low displacement power consumption.

When an electric field (voltage) is applied on the surface of a piezoelectric material, due to the elongated electric dipole moment caused by the electric field, the piezoelectric material can extend in the direction of the electric field. This mechanical deformation due to the electric field is called the reverse piezoelectric effect, which is substantially a process of converting electrical energy to mechanical energy. If the electric field is strong enough, then the piezoelectric crystal can exhibit the electrostriction effect; that is, the material strain (deformation) is proportional to the square of the applied electric field.

Therefore, piezoelectric materials are widely used in motors. For example, when a voltage is applied to the piezoelectric material, the piezoelectric material deforms to drive the motor to move. Traditionally, a composite polarization type piezoelectric actuator is produced by using piezoelectric materials having different polarizing regions and attaching them to form the composite polarization type piezoelectric actuator. However, it takes time and entails extra cost to attach the piezoelectric materials for the prior art composite polarization type piezoelectric actuator.

### SUMMARY OF THE INVENTION

It is an object of the present invention to provide a composite polarization type piezoelectric actuator that comprises a ceramic element having a plurality of polarizing directions, thereby eliminating the need to attach different piezoelectric materials.

In order to achieve the above object, the present invention provides a composite polarization type piezoelectric actuator, comprising: a ceramic element comprising a first polarizing region and a second polarizing region, wherein the first polarizing region has a first polarizing direction different from a second polarizing direction of the second polarizing region. Therefore, when a voltage is applied to the composite polarization type piezoelectric actuator, an end face of the ceramic element is deformed.

In an embodiment of the present invention, the first polarizing direction of the first polarizing region is in the direction of the X-axis, and the second polarizing direction of the second polarizing region is in the direction of the Z-axis. The ceramic element is first polarized to form the second polarizing region having the second polarizing direction in the direction of the Z-axis, and then the ceramic element is polarized to form the first polarizing region having the first polarizing direction in the direction of the X-axis or other polarizing direction other than that of the Z-axis, such as the Y-axis.

When a pulse wave voltage is applied to the composite polarization type piezoelectric actuator, the end face of the ceramic element generates an elliptical motion.

In a preferred embodiment of the present invention, the ceramic element further comprises a third polarizing region having a third polarizing direction in the direction of the X-axis, Y-axis, or Z-axis.

To reduce the labor required in manufacturing the composite polarization type piezoelectric actuator, the ceramic element can be a long and thin type of ceramic element. However, in order to generate a desired motion, the ceramic element can be formed in a ring shape. In the embodiment, the first polarizing region and the second polarizing region are both formed in ring shapes.

In order to increase the displacement of the ceramic element, two or more than two ceramic elements are laminated and attached to each other with a structural glue having a silver powder.

The composite polarization type piezoelectric actuator can be used in motors; therefore, the composite polarization type piezoelectric actuator can comprise a friction layer for driving an external element.

### BRIEF DESCRIPTION OF THE DRAWINGS

FIG. 1 illustrates a composite polarization type piezoelectric actuator of the present invention;

FIG. 2 illustrates another embodiment of the composite polarization type piezoelectric actuator of the present invention;

FIG. 3A illustrates the ceramic element of FIG. 1 having two polarizing directions;

FIG. 3B illustrates a view of the ceramic element of FIG. 3A when no voltage is applied to it;

FIG. 3C illustrates a front view of the ceramic element of FIG. 3A moving in the X-Z plane when a constant voltage is applied to it;

FIG. 3D illustrates a front view of the ceramic element of FIG. 3A moving in the X-Z plane and also the motion of the upper end face when a pulse wave voltage is applied to it;

FIG. 4A illustrates the ceramic element of FIG. 1 having two polarizing directions;

FIG. 4B illustrates a view of the ceramic element of FIG. 4A when no voltage is applied to it;

FIG. 4C illustrates a front view of the ceramic element of FIG. 4A moving in the X-Z plane when a constant voltage is applied to it;

FIG. 4D illustrates a front view of the ceramic element of FIG. 4A moving in the X-Z plane and also the motion of the upper end face when a pulse wave voltage is applied to it;

FIG. 5A illustrates the ceramic element of FIG. 1 having two polarizing directions;

FIG. 5B illustrates a view of the ceramic element of FIG. 5A when no voltage is applied to it;

FIG. 5C illustrates a front view of the ceramic element of FIG. 5A moving in the X-Z plane when a constant voltage is applied to it;

FIG. 5D illustrates a front view of the ceramic element of FIG. 5A moving in the X-Z plane and also the motion of the upper end face when a pulse wave voltage is applied to it;

FIG. 6A illustrates the ceramic element of FIG. 1 having two polarizing directions;

FIG. 6B illustrates a view of the ceramic element of FIG. 6A when no voltage is applied to it;

FIG. 6C illustrates a front view of the ceramic element of FIG. 6A moving in the X-Z plane when a constant voltage is applied to it;

FIG. 6D illustrates a front view of the ceramic element of FIG. 6A moving in the X-Z plane and also the motion of the upper end face when a pulse wave voltage is applied to it;

FIG. 7A illustrates the ceramic element of FIG. 1 having two polarizing directions;

FIG. 7B illustrates a front view of the ceramic element of FIG. 7A moving in the X-Z plane when a constant voltage is applied to it;

FIG. 7C illustrates a front view of the ceramic element of FIG. 7A moving in the X-Z plane and also the motion of the upper end face when a pulse wave voltage is applied to it;

FIG. 8A illustrates a ceramic element having three polarizing directions;

FIG. 8B illustrates a view of the ceramic element when no voltage is applied to it;

FIG. 8C illustrates a front view of the ceramic element of FIG. 8A moving in the X-Z plane when a constant voltage is applied to it;

FIG. 8D illustrates a front view of the ceramic element of FIG. 8A moving in the X-Z plane and also the motion of the upper end face when a pulse wave voltage is applied to it;

FIG. 9A illustrates a ceramic element having three polarizing directions;

FIG. 9B illustrates a view of the ceramic element of FIG. 9A when no voltage is applied to it;

FIG. 9C illustrates a front view of the ceramic element of FIG. 9A moving in the X-Z plane when a constant voltage is applied to it;

FIG. 9D illustrates a front view of the ceramic element of FIG. 9A moving in the X-Z plane and also the motion of the upper end face when a pulse wave voltage is applied to it;

FIG. 10A illustrates the ceramic element of FIG. 2 having two polarizing directions;

FIG. 10B illustrates a partial view of the ceramic element of FIG. 10A when no voltage is applied to it;

FIG. 10C illustrates a partial view of the ceramic element of FIG. 10A in motion when a constant voltage is applied to it;

FIG. 10D illustrates a partial view of the ceramic element of FIG. 10A and the motion of the upper end face when a pulse wave voltage is applied to it;

FIG. 11A illustrates a ring-shaped ceramic element having three polarizing directions;

FIG. 11B illustrates a partial view of the ceramic element of FIG. 11A when no voltage is applied to it;

FIG. 11C illustrates a partial view of the ceramic element of FIG. 11A in motion when a constant voltage is applied to it; and

FIG. 11D illustrates a partial view of the ceramic element of FIG. 11A and the motion of the upper end face when a pulse wave voltage is applied to it.

### DETAILED DESCRIPTION OF THE PREFERRED EMBODIMENT

The advantages and innovative features of the invention will become more apparent from the following detailed description when taken in conjunction with the accompanying drawings.

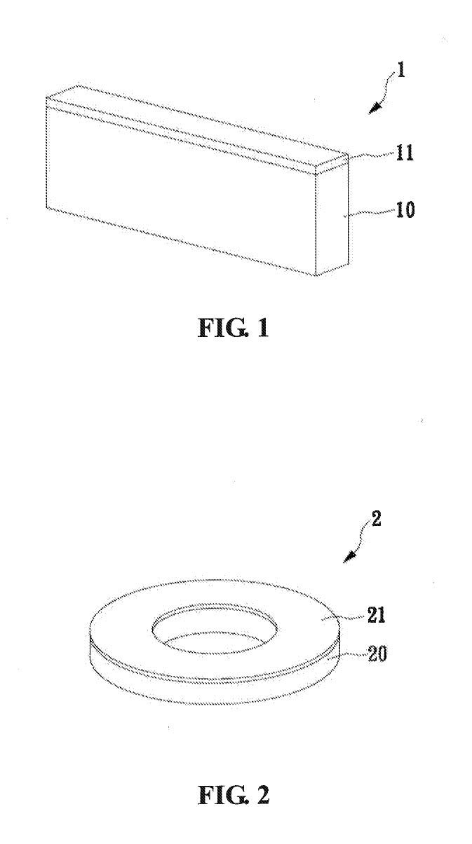

Please refer to FIG. 1 and FIG. 2. The present invention discloses a composite polarization type piezoelectric actuator that is a long and thin type of composite polarization type piezoelectric actuator 1 or a ring shaped composite polarization type piezoelectric actuator 2. Preferably, the composite polarization type piezoelectric actuator 1 comprises a ceramic element 10 and a friction layer 11. Similarly, the composite polarization type piezoelectric actuator 2 also comprises a ceramic element 20 and a friction layer 21.

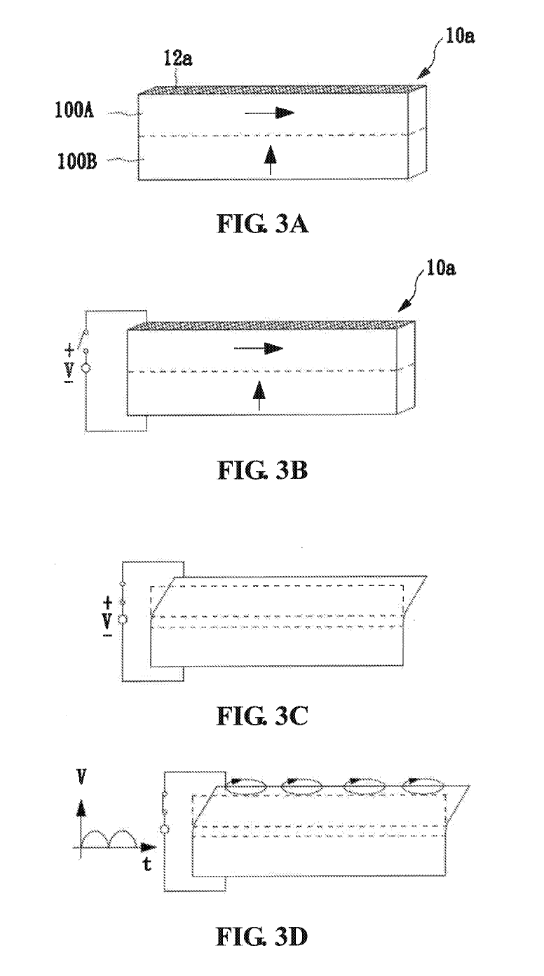

Please refer to FIG. 3A; the ceramic element 10a comprises a first polarizing region 100A and a second polarizing region 100B. In this embodiment, the polarizing direction of the first polarizing region 100A is in the positive X axis (+X axis), and the polarizing direction of the second polarizing region 100B is in the +Z axis. In the manufacturing process, the second polarizing region 100B is first polarized to have the polarizing direction in the +Z axis, and then the first polarizing region 100A is polarized to have the polarizing direction in the +X axis.

As shown in FIG. 3B, a voltage, for example from 0 to 150V, is applied to the upper and lower end faces (X-Y plane) of the ceramic element 10a. Please refer to FIG. 3C; when a constant voltage is applied to the ceramic element 10a, it will deform in the X-Z plane due to the reverse piezoelectric effect and thus generate deformations in the perpendicular and obliquely transverse directions. Please refer to FIG. 3D; when a pulse wave voltage is applied, that is, when the applied voltage increases and then decreases periodically between 0 to 150V, the upper end face 12a of the ceramic element 10a moves back and forth to generate an elliptical motion (in the clockwise direction, as shown by the arrow in FIG. 3D).

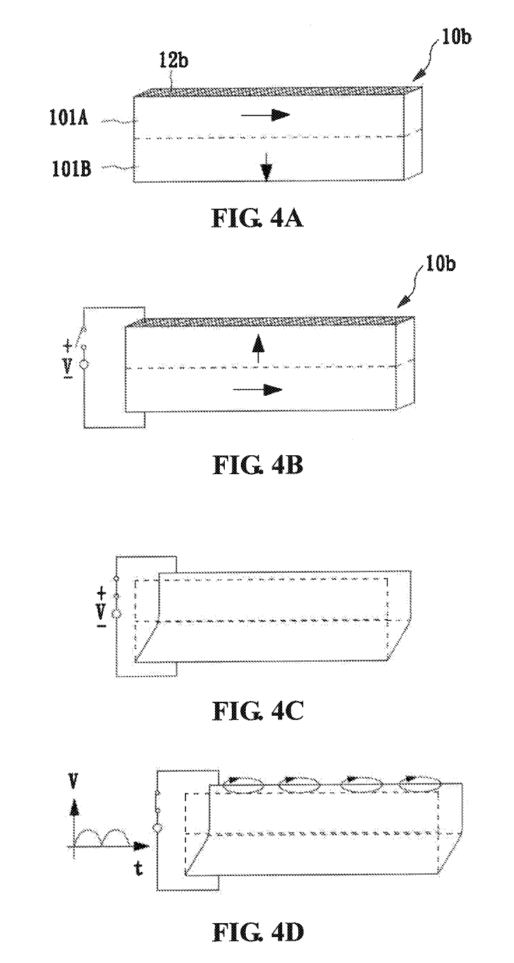

Please refer to FIG. 4A; the difference between the embodiment in FIG. 4A and that in FIG. 3A is that the polarizing direction of the second polarizing region 101B of the ceramic element 10b in FIG. 4A is in the −Z axis. The rest of the structure is the same as that in FIG. 3A.

As shown in FIG. 4B, a voltage, for example from 0 to 150V, is applied to the upper and lower end faces (X-Y plane) of the ceramic element 10b. Please refer to FIG. 4C; when a constant voltage is applied to the ceramic element 10b, it will deform in the X-Z plane due to the reverse piezoelectric effect and thus generate deformations in the perpendicular and obliquely transverse directions. Please refer to FIG. 4D; when a pulse wave voltage is applied, that is, when the applied voltage increases and then decreases periodically between 0 to 150V, the upper end face 12a of the ceramic element 10a moves back and forth to generate an elliptical motion (in the clockwise direction, as shown by the arrow in FIG. 4D).

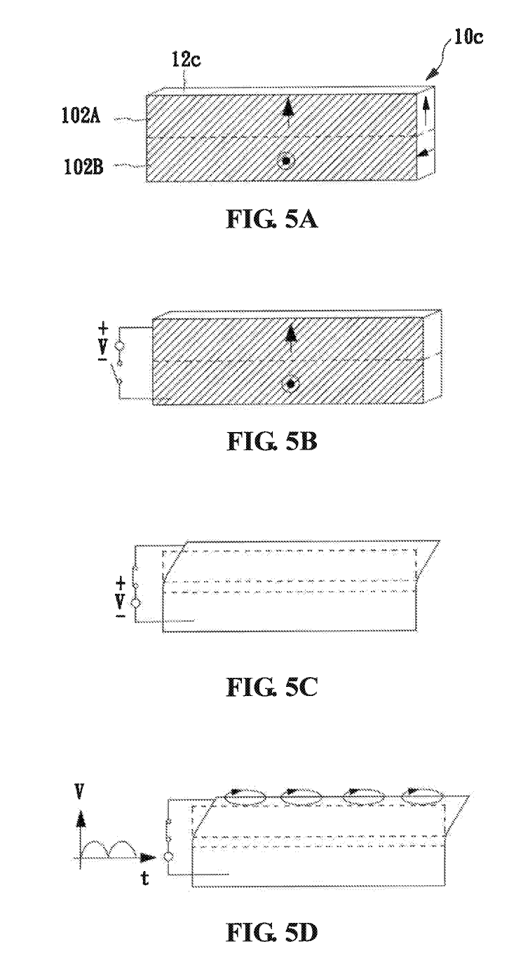

Please refer to FIG. 5A; the difference between the embodiment in FIG. 5A and that in FIG. 3A is that the polarizing direction of the first polarizing region 102A of the ceramic element 10C is in the +Z axis, and the polarizing direction of the second polarizing region 102B of the ceramic element 10C is in the +Y axis. The rest of the structure is the same as that in FIG. 3A.

In addition, the voltage, for example 0 to 150V, is applied to the front and back end faces of the ceramic element 10c (X-Z plane) in FIG. 5B. Please refer to FIG. 5C; when a constant voltage is applied to the ceramic element 10c, it will deform in the X-Z plane due to the reverse piezoelectric effect and thus generate deformations in the perpendicular and obliquely transverse directions, similar to those shown in FIG. 3C. Please refer to FIG. 5D; when a pulse wave voltage is applied, that is, when the applied voltage increases and then decreases periodically between 0 to 150V, the upper end face 12c of the ceramic element 10c moves back and forth to generate an elliptical motion (in the clockwise direction, as shown by the arrow in FIG. 5D).

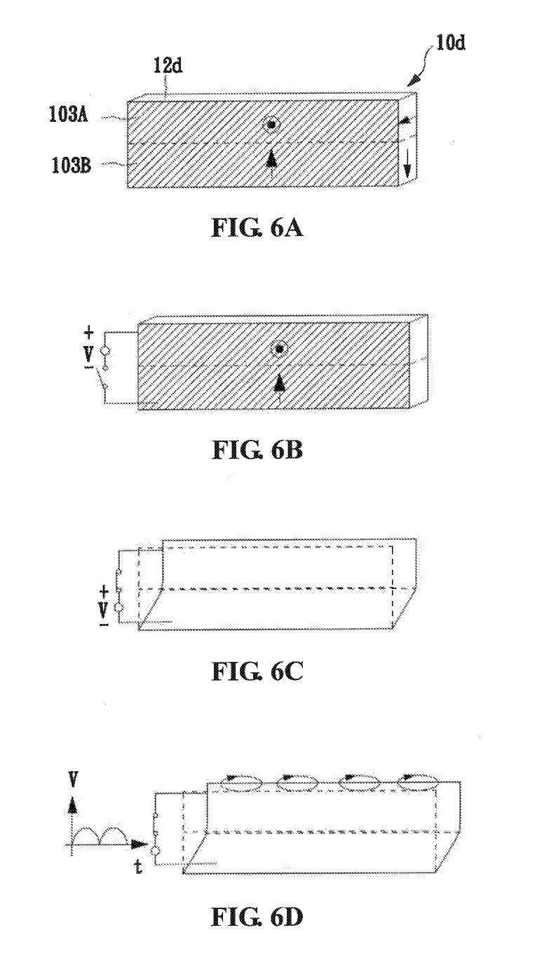

Please refer to FIG. 6A; the difference between the embodiment in FIG. 6A and that in FIG. 5A is that the polarizing direction of the first polarizing region 103A of the ceramic element 10d is in the +Y axis, and the polarizing direction of the second polarizing region 103B of the ceramic element 10d is in the +Z axis. The rest of the structure is the same as that in FIG. 5A.

As shown in FIG. 6B, the voltage, for example 0 to 150V, is applied to the front and back end faces of the ceramic element 10d (X-Z plane). Please refer to FIG. 6C; when a constant voltage is applied to the ceramic element 10c, it will deform in the X-Z plane due to the reverse piezoelectric effect and thus generate deformations in the perpendicular and obliquely transverse directions similar to those shown in FIG. 4C. Please refer to FIG. 6D; when a pulse wave voltage is applied, that is, when the applied voltage increases and then decreases periodically between 0 to 150V, the upper end face 12d of the ceramic element 10d moves back and forth to generate an elliptical motion (in the clockwise direction, as shown by the arrow in FIG. 6D).

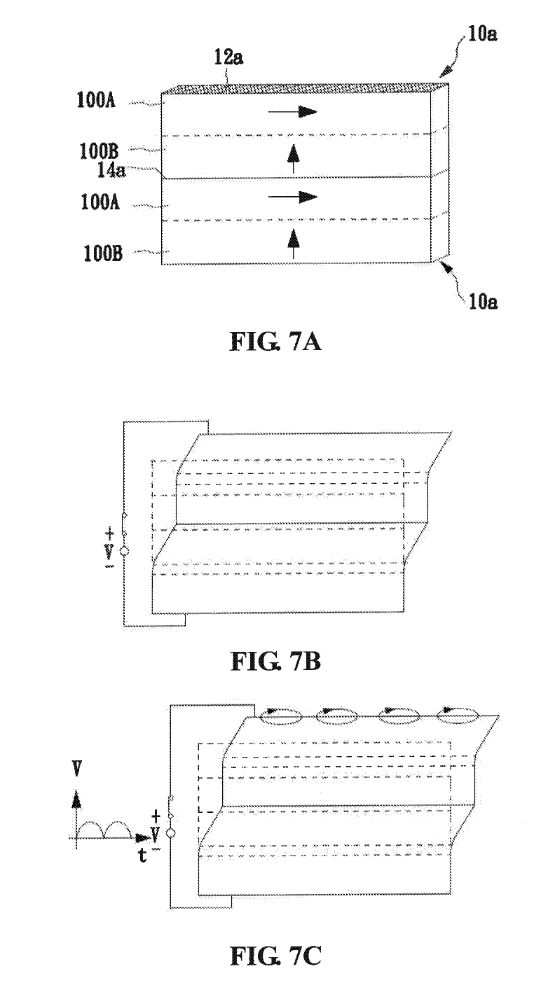

In order to increase the amount of displacement of the ceramic element, the present invention provides a structure of two or more than two ceramic elements laminated with structural glue having a silver powder. Please refer to FIG. 7A, which shows two ceramic elements of FIG. 3A laminated to each other and attached by the structural glue having a silver powder at the joint 14a.

As described above, a voltage, for example 0 to 150V, is applied to the upper and lower end faces of the ceramic element 10a (X-Y plane). Please refer to FIG. 7B; when a constant voltage is applied to the ceramic element 10a, it will deform in the X-Z plane due to the reverse piezoelectric effect and thus generate deformations in the perpendicular and obliquely transverse directions; furthermore, due to the accumulated effects of both ceramic elements, the displacement is even greater than that shown in FIG. 3A. Please refer to FIG. 7C; when a pulse wave voltage is applied, that is, when the applied voltage increases and then decreases periodically between 0 to 150V, the upper end face 12a of the ceramic element 10a moves back and forth to generate an elliptical motion (in the clockwise direction, as shown by the arrow in FIG. 7C).

In addition to the embodiments described above, the ceramic element can have more than two different polarizing regions; for example, it can comprise a third polarizing region. The third polarizing region can be the same as the first or second polarizing region, or it can be different from the first or second polarizing region.

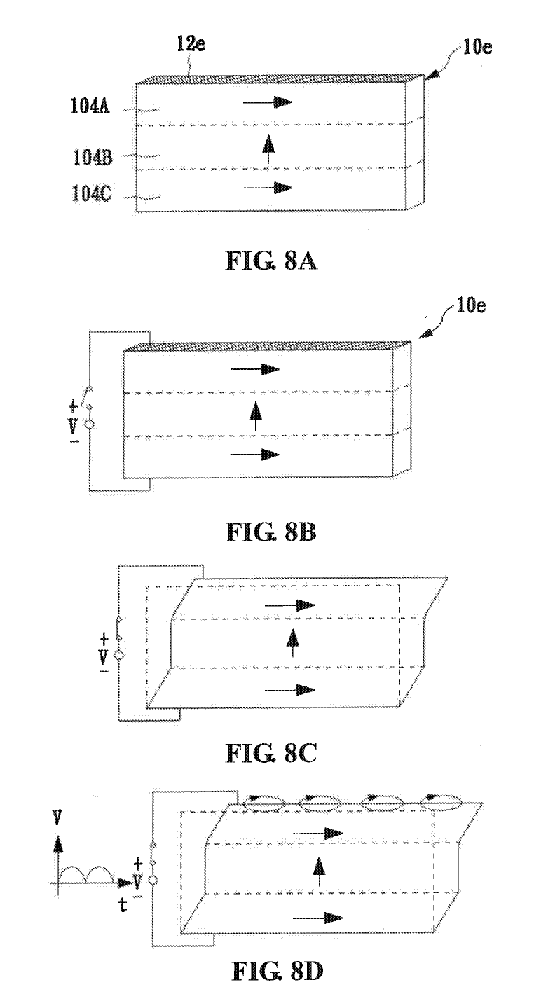

Please refer to FIG. 8A; the ceramic element 10e comprises a first polarizing region 104A, a second polarizing region 104B, and a third polarizing region 104C. In this embodiment, the polarizing direction of the first polarizing region 104A is in the +X axis, the polarizing direction of the second polarizing region 104B is in the +Z axis, and the polarizing direction of the third polarizing region 104C is also in the +X axis. In the manufacturing process, the second polarizing region 104B is first polarized to have the polarizing direction in the +Z axis, and then the first polarizing region 104A and the third polarizing region 104C are polarized to have the polarizing direction in the +X axis.

As shown in FIG. 8B, a voltage, for example from 0 to 150V, is applied to the upper and lower end faces (X-Y plane) of the ceramic element 10a. Please refer to FIG. 8C; when a constant voltage is applied to the ceramic element, it will deform in the X-Z plane due to the reverse piezoelectric effect and thus generate deformations in the perpendicular and obliquely transverse directions. The amount of the displacement is also greater than that in FIG. 3A. Please refer to FIG. 8D; when a pulse wave voltage is applied, that is, when the applied voltage increases and then decreases periodically between 0 to 150V, the upper end face 12e of the ceramic element 10e moves back and forth to generate an elliptical motion (in the clockwise direction, as shown by the arrow in FIG. 8D).

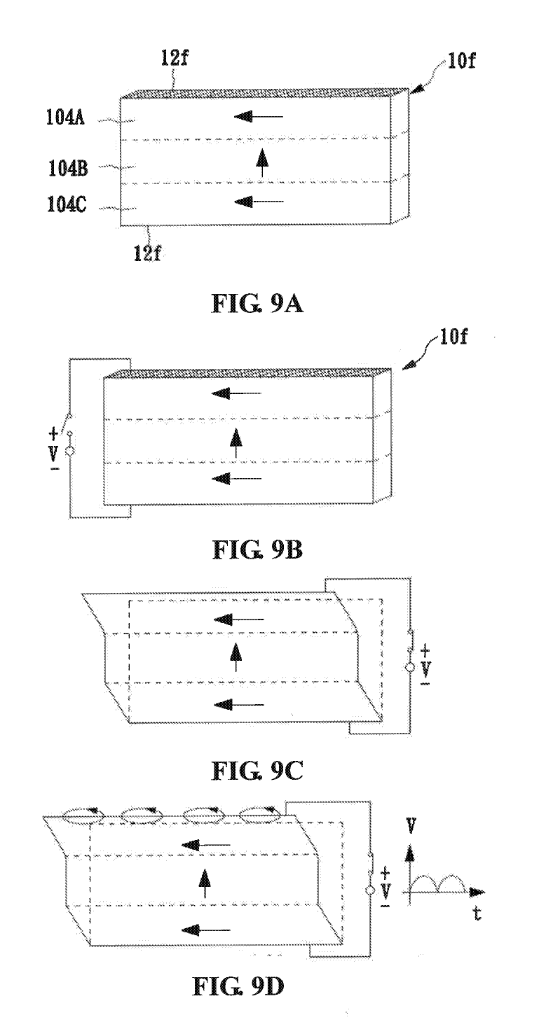

The difference between the embodiment in FIG. 9A and that in FIG. 8A is that the polarizing direction of the first polarizing region 105A and the third polarizing direction 105C of the ceramic element 10d are in the −X axis. The rest of the structure is the same as that in FIG. 8A.

As shown in FIG. 9B, a voltage, for example from 0 to 150V, is applied to the upper and lower end face (X-Y plane) of the ceramic element 10f. Please refer to FIG. 9C; when a constant voltage is applied to the ceramic element, it will deform in the X-Z plane due to the reverse piezoelectric effect and thus generate deformations in the perpendicular and obliquely transverse direction. The amount of the displacement is also greater than that of the embodiments having two polarizing regions. Please refer to FIG. 9D; when a pulse wave voltage is applied, that is, when the applied voltage increases and then decreases periodically between 0 to 150V, the upper end face 12f of the ceramic element 10f moves back and forth to generate an elliptical motion (in the counterclockwise direction, as shown by the arrow in FIG. 9D).

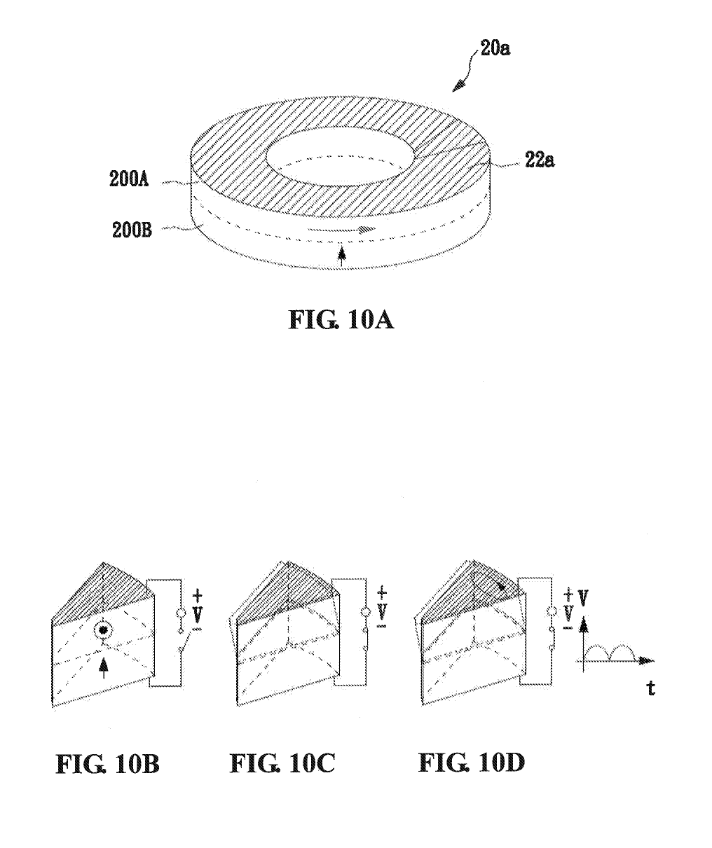

Please refer to FIG. 10A; the ceramic element 20a comprises a first polarizing region 200A and a second polarizing region 200B. In this embodiment, the polarizing region 200A and the second polarizing region 200B are formed in ring shapes; the polarizing direction of the first polarizing region 200A is in the counterclockwise direction, and the polarizing direction of the second polarizing region 200B is in the +Z axis. In the manufacturing process, the second polarizing region 200B is first polarized to have the polarizing direction in the +Z axis, and then the first polarizing region 200A is polarized to have the polarizing direction in the counterclockwise direction.

In order to better illustrate the motion of the ceramic element 20a, only a part of the ceramic element 20a is shown. As shown in FIG. 10B, a voltage, for example from 0 to 150V, is applied to the upper and lower end faces (X-Y plane) of the ceramic element 20a. Please refer to FIG. 10C; when a constant voltage is applied to the ceramic element 20a, it will deform due to the reverse piezoelectric effect and thus generate a deformation in the perpendicular direction and a twisting deformation in the counterclockwise direction. Please refer to FIG. 10D; when a pulse wave voltage is applied, that is, when the applied voltage increases and then decreases periodically between 0 to 150V, the upper end face 22a of the ceramic element 20a moves back and forth to generate an elliptical motion (in the counterclockwise direction, as shown by the arrow in FIG. 10D).

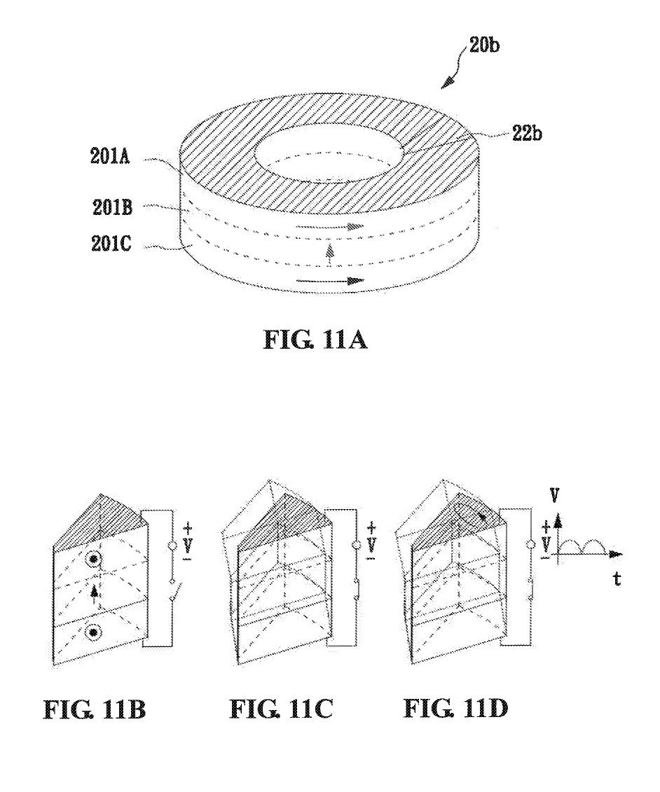

Similar to FIG. 9A, the ring-shaped ceramic element can be designed to have three polarizing regions. Please refer to FIG. 11A; the ring shaped ceramic element 20b comprises a first polarizing region 201A, a second polarizing region 201B, and a third polarizing region 201C. In this embodiment, the polarizing direction of the first polarizing region 201A is in the counterclockwise direction, the polarizing direction of the second polarizing region 201B is in the +Z axis, and the polarizing direction of the third polarizing region 201C is also in the counterclockwise direction.

In order to better illustrate the motion of the ceramic element 20a, only a part of the ceramic element 20b is shown. As shown in FIG. 11B, a voltage, for example from 0 to 150V, is applied to the upper and lower end faces (X-Y plane) of the ceramic element 20b. Please refer to FIG. 11C; when a constant voltage is applied to the ceramic element 20b, it will deform due to the reverse piezoelectric effect and thus generate a deformation in the perpendicular direction and a twisting deformation in the counterclockwise direction. The amount of the displacement is obviously greater than that of the ceramic element 20a having two polarizing regions in FIG. 10C. Please refer to FIG. 11D; when a pulse wave voltage is applied, that is, when the applied voltage increases and then decreases periodically between 0 to 150V, the upper end face 22b of the ceramic element 20b moves back and forth to generate an elliptical motion (in the counterclockwise direction, as shown by the arrow in FIG. 11D). In this embodiment, the amount of the displacement is also much greater than that of the ceramic element 20a having two polarizing regions in FIG. 10D.

In the manufacturing process, the ceramic element is first polarized to form the polarizing region having the polarizing direction in the direction of the Z-axis, and then the ceramic element is polarized to form the polarizing region having the polarizing direction in the direction of the X-axis or the Y-axis. The user can design a ceramic element having a plurality of different polarizing regions based on the desired type(s) of motions. Therefore, the figures are only for illustration and not for limiting the present invention.

The composite polarization type piezoelectric actuator disclosed in the present invention can be used by a motor; therefore, the composite polarization type piezoelectric actuator can further comprises a friction layer for driving an external element to move back and forth.

It is noted that the above-mentioned embodiments are only for illustration. It is intended that the present invention cover modifications and variations of this invention provided they fall within the scope of the following claims and their equivalents. Therefore, it will be apparent to those skilled in the art that various modifications and variations can be made to the structure of the present invention without departing from the scope or spirit of the invention.

What is claimed is:

1. A composite polarization type piezoelectric actuator, comprising:
a ceramic element comprising a first polarizing region and a second polarizing region, wherein the first polarizing region has a first polarizing direction different from a second polarizing direction of the second polarizing region;
whereby, when a voltage is applied to the composite polarization type piezoelectric actuator, an end face of the ceramic element is deformed.

2. The composite polarization type piezoelectric actuator as claimed in claim 1, wherein the first polarizing direction of the first polarizing region is in the direction of the X-axis, and the second polarizing direction of the second polarizing region is in the direction of the Z-axis.

3. The composite polarization type piezoelectric actuator as claimed in claim 2, wherein the ceramic element is first polarized to form the second polarizing region having the second polarizing direction in the direction of the Z-axis, and then the ceramic element is polarized to form the first polarizing region having the first polarizing direction in the direction of the X-axis.

4. The composite polarization type piezoelectric actuator as claimed in claim 2, wherein when a pulse wave voltage is applied to the composite polarization type piezoelectric actuator, the end face of the ceramic element generates an elliptical motion.

5. The composite polarization type piezoelectric actuator as claimed in claim 4, further comprising a friction layer disposed on the end face of the ceramic element; the friction layer can be used to drive an external element when the end face generates the elliptical motion.

6. The composite polarization type piezoelectric actuator as claimed in claim 1, wherein the ceramic element further comprises a third polarizing region having a third polarizing direction in the direction of the X-axis, the Y-axis, or the Z-axis.

7. The composite polarization type piezoelectric actuator as claimed in claim 1, wherein the ceramic element is formed in a ring shape, and the first polarizing region and the second polarizing region are also formed in a ring shape.

8. The composite polarization type piezoelectric actuator as claimed in claim 7, wherein when a pulse wave voltage is applied to the composite polarization type piezoelectric actuator, the end face of the ceramic element generates a twisting motion in the clockwise direction or the counterclockwise direction.

9. The composite polarization type piezoelectric actuator as claimed in claim 8, further comprising a friction layer disposed on the end face of the ceramic element; the friction layer can be used to drive an external element when the end face generates the twisting motion in the clockwise direction or the counterclockwise direction.

10. The composite polarization type piezoelectric actuator as claimed in claim 1, further comprising a second ceramic element comprising a third polarizing region and a fourth polarizing region, wherein the third polarizing region has a third polarizing direction different from a fourth polarizing direction of the fourth polarizing region; wherein the second ceramic element is laminated on the first ceramic element, and the second ceramic element and the first ceramic element are attached to each other with a structural glue having a silver powder.
